(19) United States
(12) Patent Application Publication
(10) Pub. No.: US 2019/0049160 A1
(43) Pub. Date: Feb. 14, 2019

(54) SOLAR COOLING SYSTEM

(71) Applicant: KING FAHD UNIVERSITY OF PETROLEUM AND MINERALS, Dhahran (SA)

(72) Inventors: Esmail Mohamed Ali MOKHEIMER, Dhahran (SA); Yahya Esmail Mohamed Ali MOKHEIMER, Dhahran (SA)

(73) Assignee: KING FAHD UNIVERSITY OF PETROLEUM AND MINERALS, Dhahran (SA)

(21) Appl. No.: 15/673,987

(22) Filed: Aug. 10, 2017

(51) Int. Cl. F25B 27/00; F25B 21/02; H01L 35/32; H02S 10/10; H02S 20/30; H02S 40/38; H02S 40/42; H02S 99/00; H02J 7/35; H02J 7/00

(52) U.S. Cl. CPC F25B 27/002; F25B 21/02; H01L 35/325; H02S 10/10; H02S 20/30; H02J 2007/0049; H02S 40/42; H02S 99/00; H02J 7/35; H02J 7/0047; H02S 40/38

(57) ABSTRACT

A solar cooling system including a support structure, a plurality of photovoltaic modules affixed to the support structure to receive sunlight and provide solar electricity, a plurality of thermoelectric generator modules affixed to support structure to receive temperature gradient and provide thermal electricity, a plurality of thermoelectric cooling modules affixed to the support structure to receive input electricity and provide cooling, and a battery assembly affixed to the support structure and electrically connected to the plurality of photovoltaic modules and the plurality of thermoelectric generator modules to receive, regulate, and store the solar electricity and the thermal electricity and provide the input electricity.

### BACKGROUND

### Field of the Disclosure

The present disclosure relates to cooling systems. Notably, to system that harvests sunlight and heat to generate cooling.

### Description of the Related Art

Nowadays, providing cooling and achieving thermal comfort is essential, notably in hot weather climates where temperatures reach levels that impede people from carrying normal day-to-day activities.

To fulfill such a demand in thermal comfort, air conditioning systems that rely on vapor-compression cycles have been employed.

Although such conventional air conditioning systems are widely employed, they present important drawbacks. Notably, such conventional air conditioning systems can be noisy, cumbersome, energy consuming, unreliable, and not environmental friendly. These conventional air conditioning systems can rely on phase change cycles on coolant fluids that require numerous moving parts and complex interactions between these moving parts reducing efficiency and reliability See Zemansky, M. and Dittman, R., Heat and Thermodynamic, Sixth ed., McGraw-Hill Book Company, 1981, pp. 431-442; Riffat, S. and Xiaoli, M., 2003. Thermoelectrics: a review of present and potential applications. Applied Thermal Engineering 23 913-935; Riffat, S. and Xiaoli, M., 2004. Comparative investigation of thermoelectric air-conditioners versus vapor compression and absorption air-conditioners. Applied Thermal Engineering 24 1979-1993; Adroja, M. Nikunj; B. Mehta, Shruti; Shah, M. Pratik 2015. Review of thermoelectricity to improve energy quality, International Journal of Emerging Technologies and Innovative Research, Vol. 2, Issue 3, page no. 847-850; and Bansal, P. K., and Martin, A. 2000. Comparative study of vapour compression, thermoelectric and absorption refrigerators. International Journal of Energy Research, 24(2), 93-107. In addition, these conventional air conditioning systems can be prone to leaks which can have negative environmental effects.

These conventional air conditioning systems may be coupled to external conventional harvesting energy systems that harvest sunlight See Elsheikh, M. H., Shnawah, D. A., Sabri, M. F. M., Said, S. B. M., Hassan, M. H., Bashir, M. B. A., and Mohamad, M. 2014. A review on thermoelectric renewable energy: Principle parameters that affect their performance. Renewable and Sustainable Energy Reviews, 30, 337-355; and Anand S. Joshi, Ibrahim Dincer, Bale V. Reddy 2009. Performance analysis of photovoltaic systems: A review, Renewable and Sustainable Energy Reviews 13 and/or other source of energy See Lee, J. J., Yoo, D., Park, C., Choi, H. H., & Kim, J. H. 2016. All organic-based solar cell and thermoelectric generator hybrid device system using highly conductive PEDOT: PSS film as organic thermoelectric generator. Solar Energy, 134, 479-483; and Park, K. T., Shin, S. M., Tazebay, A. S., Um, H. D., Jung, J. Y., Jee, S. W., Oh, M. W., Park, S. D., Yoo, B., Yu, C. and Lee, J. H. 2013. Lossless hybridization between photovoltaic and thermoelectric devices. Scientific reports, 3, such as human body heat See Siddique, A. R. M., Rabari, R., Mahmud, S., & Van Heyst, B. 2016. Thermal energy harvesting from the human body using flexible thermoelectric generator (FTEG) fabricated by a dispenser printing technique. Energy, 115, 1081-1091; Bahk, J. H., Fang, H., Yazawa, K., and Shakouri, A. 2015. Flexible thermoelectric materials and device optimization for wearable energy harvesting. Journal of Materials Chemistry C, 3(40), 10362-10374; Lu, Z., Zhang, H., Mao, C., and Li, C. M. 2016. Silk fabric-based wearable thermoelectric generator for energy harvesting from the human body. Applied Energy, 164, 57-63; and Kim, S. J., We, J. H., and Cho, B. J. 2014. A wearable thermoelectric generator fabricated on a glass fabric. Energy & Environmental Science, 7(6), 1959-1965. However, the coupling with conventional harvesting energy systems may not increase the efficiency, and/or the reliability of the conventional air conditioning systems as these conventional air conditioning systems still rely on phase change cycles of coolant fluids.

Thus, a cooling system solving the aforementioned limitations of efficiency, reliability, and environmental friendliness is desired.

### SUMMARY

Accordingly, one object of the present disclosure is to provide a solar cooling system which overcomes the above-mentioned limitations of efficiency, reliability, and environmental friendliness.

The solar cooling system of the present disclosure cools in an efficient, reliable, and environmental friendly way by relying on thermoelectric modules that directly harvest solar energy and extract heat via Peltier and Seebeck effects.

In one non-limiting illustrative example, a solar cooling system is presented. The solar cooling system includes a support structure articulable between an open position and a closed position, the support structure having a pole, a cap affixed to an upper portion of the pole, and a plurality of slats rotatably affixed to the cap, wherein in the open position the plurality of slats radially protrudes from the cap and in the closed position the plurality of slats is adjacent to the pole, a plurality of photovoltaic modules affixed to the plurality of slats to receive sunlight and provide solar electricity when the support structure is in the open position, optionally a plurality of thermoelectric generator modules affixed to the plurality of slats to receive temperature gradient and provide thermal electricity when the support structure is in the open position a plurality of thermoelectric cooling modules affixed to the plurality of slats to receive input electricity and provide cooling when the support structure is in the open position; and a battery assembly affixed to the pole and electrically connected to the plurality of photovoltaic modules and the plurality of thermoelectric generator modules to receive, regulate, and store the solar electricity and the thermal electricity and provide the input electricity.

In one non-limiting illustrative example, a solar cooling system to harvest solar energy is presented. The solar cooling system includes a support structure, a plurality of photovoltaic modules affixed to the support structure to receive sunlight and provide solar electricity, optionally a plurality of thermoelectric generator modules affixed to support structure to receive temperature gradient and provide thermal electricity, a plurality of thermoelectric cooling modules affixed to the support structure to receive input electricity and provide cooling, a battery assembly affixed to the support structure and electrically connected to the plurality of photovoltaic modules and the plurality of thermoelectric generator modules to receive, regulate, and store the solar electricity and the thermal electricity and provide the input electricity, and an electrical control unit configured to detect a cooling demand and to actuate the plurality of thermoelectric cooling modules to provide cooling.

In one non-limiting illustrative example, a solar cooling system to harvest solar energy is presented. The solar cooling system includes a support structure, a plurality of photovoltaic modules affixed to the support structure to receive sunlight and provide solar electricity, optionally a plurality of thermoelectric generator modules affixed to support structure to receive temperature gradient and provide thermal electricity, a plurality of thermoelectric cooling modules affixed to the support structure to receive input electricity and provide cooling, and a battery assembly affixed to the support structure and electrically connected to the plurality of photovoltaic modules and the plurality of thermoelectric generator modules to receive, regulate, and store the solar electricity and the thermal electricity and provide the input electricity.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1A is a perspective view of a solar cooling system in an open position, according to certain aspects of the disclosure;

FIG. 1B is a perspective view of the solar cooling system in a closed position, according to certain aspects of the disclosure;

FIG. 2A is a perspective view of a support structure of the solar cooling system in the open position, according to certain aspects of the disclosure;

FIG. 2B is a perspective view of the support structure of the solar cooling system in the closed position, according to certain aspects of the disclosure;

FIG. 3 is diagram of a thermoelectric generator module of the solar cooling system, according to certain aspects of the disclosure;

FIG. 4 is diagram of a thermoelectric cooling module of the solar cooling system, according to certain aspects of the disclosure;

FIG. 5 is a schematic view of a battery assembly of the solar cooling system, according to certain aspects of the disclosure;

FIG. 6 is a flow chart of a method for providing cooling through the solar cooling system, according to certain aspects of the disclosure;

FIG. 7 is a perspective view of the solar cooling system with an evaporation system Z, according to certain aspects of the disclosure; and

FIG. 8 is a schematic view of a hardware diagram of an electrical control unit for operating the solar cooling system, according to certain aspects of the disclosure.

### DETAILED DESCRIPTION

All publications, patent applications, patents, and other references mentioned herein are incorporated by reference in their entirety. Further, the materials, methods, and examples discussed herein are illustrative only and are not intended to be limiting.

In the drawings, like reference numerals designate identical or corresponding parts throughout the several views. Further, as used herein, the words “a”, “an”, and the like include a meaning of “one or more”, unless stated otherwise. The drawings are generally drawn not to scale unless specified otherwise or illustrating schematic structures or flowcharts.

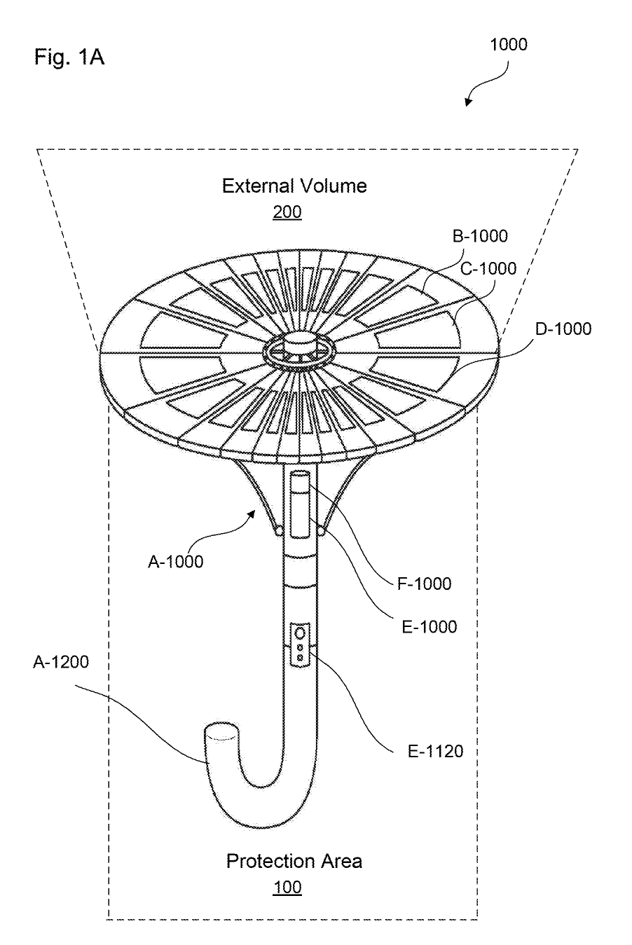

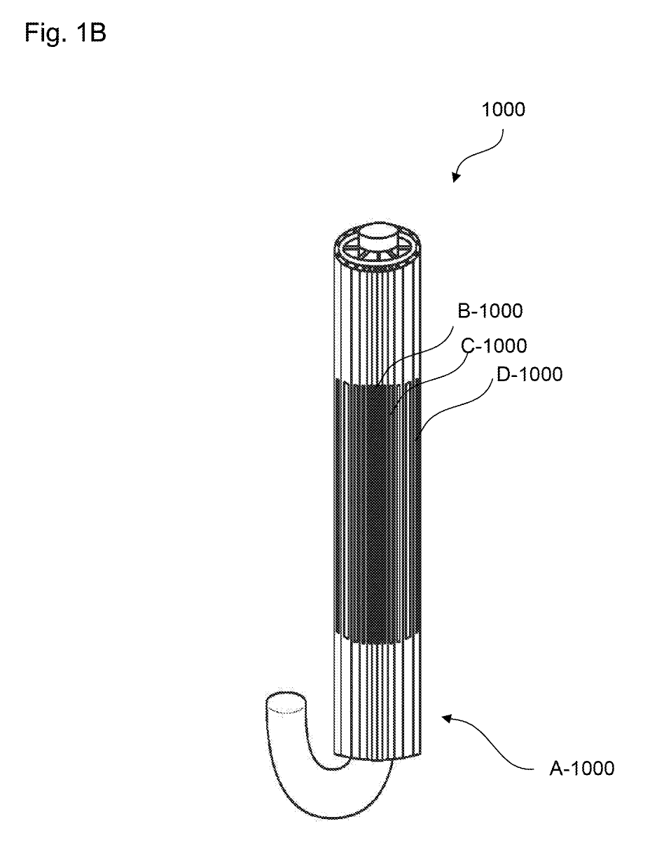

FIGS. 1A-1B are perspective views of a solar cooling system 1000 in an open position and in a closed position, according to certain aspects of the disclosure.

The solar cooling system 1000 can efficiently harvest solar energy via p-n junctions and photovoltaic cells that convert sunlight and heat into electrical energy and provide cooling by using the electrical power.

The solar cooling system 1000 can include a support structure A-1000, a plurality of photovoltaic modules B-1000 affixed to the support structure, a plurality of thermoelectric generator modules C-1000 affixed to the support structure A-1000, a plurality of thermoelectric cooling modules D-1000 affixed to the support structure A-1000, a battery assembly E-1000 affixed to the support structure A-1000 and electrically connected to the plurality of photovoltaic modules B-1000, the plurality of thermoelectric generator modules C-1000 and the plurality of thermoelectric cooling modules D-1000, and an electrical control unit F-1000 in communication with the plurality of photovoltaic modules B-1000, the plurality of thermoelectric generator modules C-1000, the plurality of thermoelectric modules D-1000, and the battery assembly E-1000.

The support structure A-1000 can support the plurality of photovoltaic modules B-1000, the plurality of thermoelectric generator modules C-1000 and the plurality of thermoelectric cooling modules D-1000, and be articulated between an open position, as illustrated in FIG. 1A, and a closed position, as illustrated in FIG. 1B.

In the open position, the solar cooling system 1000 can provide a protection area 100, as illustrated in FIG. 1A, wherein an user can be protected from sunlight and heat and be cooled by the plurality of thermoelectric cooling modules D-1000, and an external volume 200, as illustrated in FIG. 1A, wherein the plurality of photovoltaic modules B-1000 can be exposed to sunlight and the plurality of thermoelectric generator modules C-1000 can be exposed to heat.

In the closed position, the solar cooling system 1000 can minimize the exposure of the plurality of photovoltaic modules B-1000 to sunlight and facilitate the storage and/or transport of the solar cooling system 1000 by minimizing the span of the solar cooling system 1000.

The plurality of photovoltaic modules B-1000 can harvest the sunlight to generate solar input electricity SIe, the plurality of thermoelectric generator modules C-1000 can harvest heat present in the external volume 200 to generate thermal input electricity HIe, and the plurality of thermoelectric cooling modules D-1000 can receives output electricity Oe to generate cooling in the protected area 100.

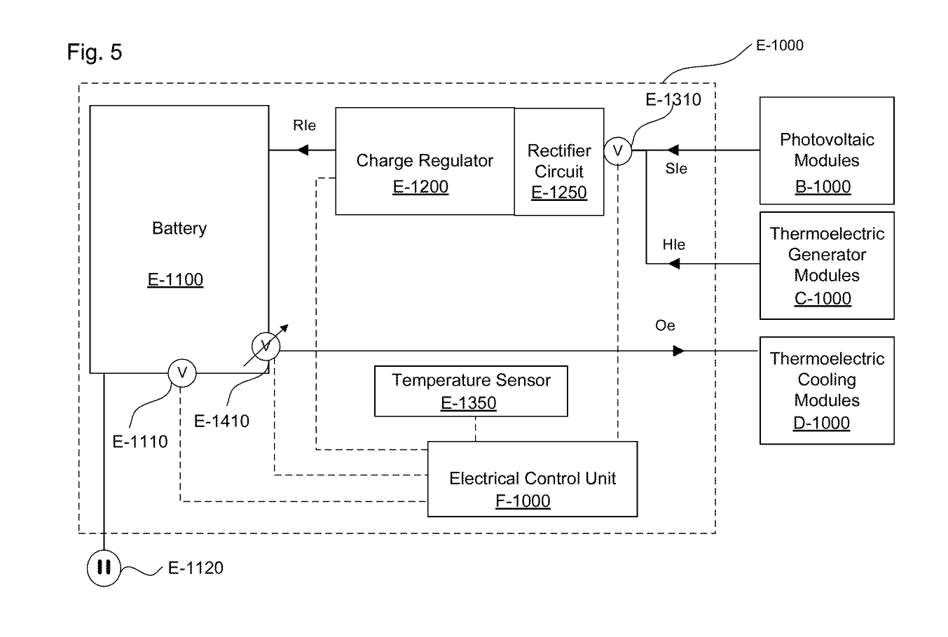

The battery assembly E-1000 can receive, convert, store the solar input electricity SIe and the thermal input electricity HIe, and provide the output electricity Oe to the plurality of thermoelectric cooling modules D-1000, as illustrated in FIG. 5. In addition, stored energy can be later used in external elements of the solar cooling system 1000, e.g. electronic devices, and/or electric chargers, through an electrical connection E-1120, e.g. an USB connection, and/or an electrical outlet, as illustrated in FIGS. 1A and 5.

The electrical control unit F-1000 can be configured to manage the battery assembly E-1000 in order to optimize and/or maximize energy harvested by solar cooling system 1000.

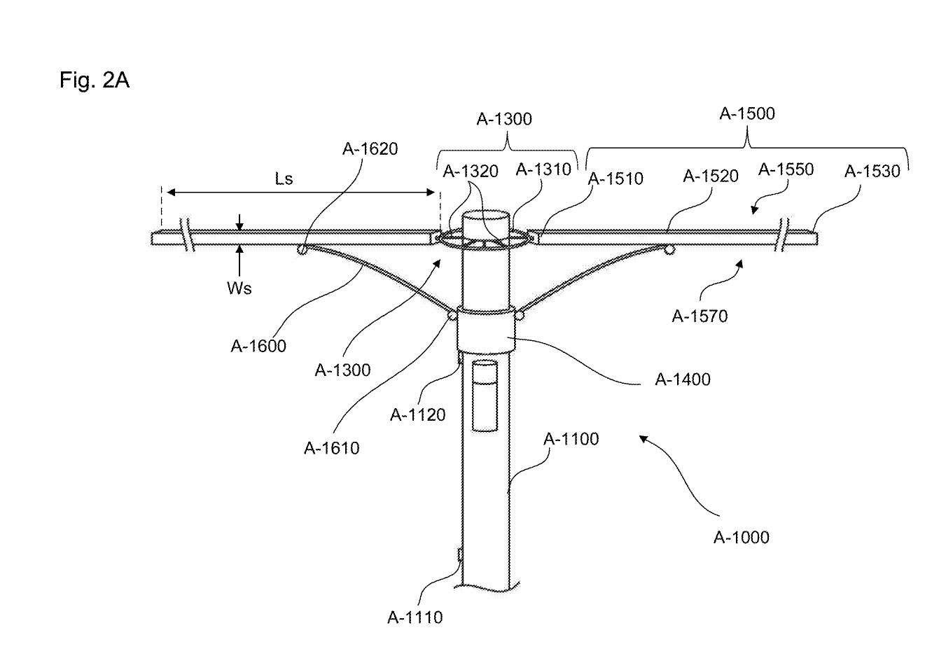

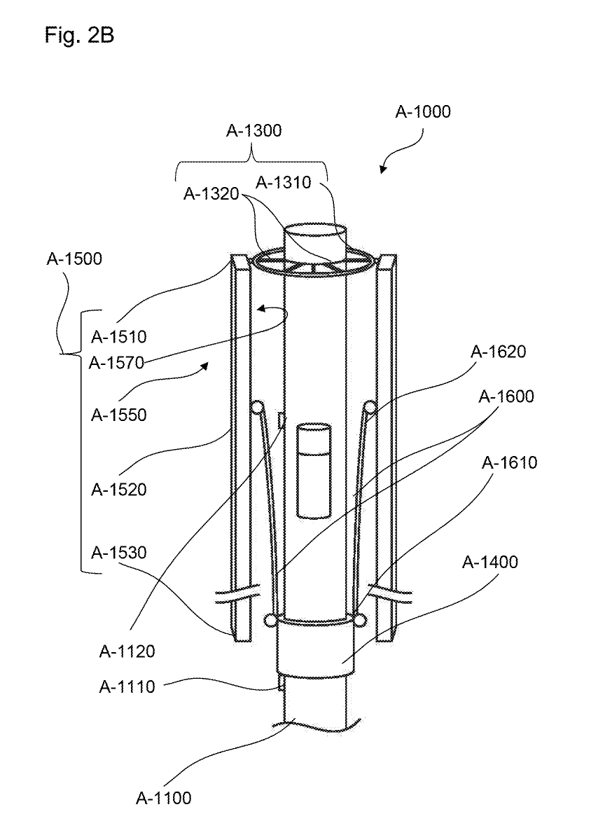

FIGS. 2A-2B are perspective views of the support structure A-1000 of the solar cooling system 1000 in the open position and in the closed position, according to certain aspects of the disclosure.

The support structure A-1000 can include a pole A-1100, a handle A-1200 positioned at a bottom portion of the pole A-100, as illustrated in FIG. 1A, a cap A-1300 affixed to a top portion of the pole A-1100, a plurality of slats A-1500 that radially protrudes from the cap A-1300, a runner ring A-1400 that slides along the pole A-1100, and a plurality of arms A-1600 that radially extends between the runner ring A-1400 and slat central portions A-1520 of the plurality of slats A-1500.

The pole A-1100 can provide support for the solar cooling system 1000 and storage for the battery assembly E-1000. For example, the pole A-1100 can be a rigid tube, e.g. metallic and/or plastic tube, having an internal volume to house the battery assembly E-1000 and an external surface that receives the electrical connection E-120, as illustrated in FIG. 1A.

In addition, the pole A-1100 can include a bottom latch A-110 positioned above the handle A-1200 that engages the runner ring A-1400 and locks the solar cooling system 1000 in the closed position, and a top latch A-1120 positioned below the cap A-1300 that engages the runner ring A-1400 and locks the solar cooling system 1000 in the open position.

Each arm of the plurality of arms A-1600 can include an arm inner portion A-1610 rotatably affixed to the runner ring A-1400 and an arm outer portion A-1620 rotatably affixed to the slat central portion A-1520 of each slat A-1500.

The cap A-1300 can include an annulus A-1310 centered on the pole A-1100 and a plurality of branches A-1320 extending radially between the pole A-1100 and the annulus A-1310.

Each slat of the plurality of slats A-1500 can have a slat inner portion A-1510 rotatably affixed to the annulus A-1310 of the cap A-1300, a slat outer portion A-1530 free, a slat external surface A-1550 that supports a photovoltaic module B-1000 and/or a thermoelectric generator module C-1000, and a slat internal surface A-1570 that supports a thermoelectric cooling module D-1000.

The plurality of slats A-1500 can have dimensions to cover, in the open position, a predetermined number of persons Np while being capable to be manually transported by a restricted number of persons RNp in the closed position. For example, each slat of the plurality of slats A-1500 can have a length Ls between 0.20 m and 5.0 m, and preferably between 0.5 m and 1.0 m and a width Ws between 1 cm and 20 cm, and preferably between 5 cm and 10 cm, for the predetermined number of persons Np being between 1 and 100, and for the restricted number of persons RNp being between 1 and 10.

The plurality of photovoltaic modules B-1000, the plurality of thermoelectric generator modules C-1000, and the plurality of thermoelectric cooling modules D-1000 can be electrically connected to the battery assembly E-1000 via electric wires passing through internal volumes of the plurality of slats A-1500 and through the internal volume of the pole A-1100.

To articulate the solar cooling system 1000 from the closed position to the open position, the user can slide the runner ring A-1400 along the pole A-1100 from the bottom latch A-1110 to the top latch A-1120. The sliding motion of the runner ring A-1400 along the pole A-1100 pushes, via the plurality of arms A-1600, the plurality of slats A-1500 in upward direction and forces the slat inner portions A-1510 to rotate around the annulus A-1310. The rotation of the slat central portions A-1520 places the plurality of slats A-1500 adjacent to each and radially from the cap A-1300 to have the slat external surfaces A-1550 exposed to the sunlight and heat and the slat internal surfaces A-1570 covering the user.

In the open position, the slat external surfaces A-1550 of the plurality of slats A-1500 can be exposed to the sunlight and heat and allow the plurality of photovoltaic modules and the plurality of thermoelectric generator modules C-1000 to generate the solar input electricity SIe and the thermal input electricity HIe, respectively. Similarly, when the solar cooling system 1000 is articulated in the open position, the slat internal surfaces A-1570 of the plurality of slats A-1500 can face the user holding the pole A-1100 to allow the plurality of thermoelectric cooling modules D-1000 to provide cooling for the user.

To articulate the solar cooling system 1000 from the open position to the closed position, the user can slide the runner ring A-1400 along the pole A-1100 from the top latch A-1120 to the bottom latch A-1110. The sliding motion of the runner ring A-1400 along the pole A-1100 pulls, via the plurality of arms A-1600, the plurality of slats A-1500 in downward direction and forces the slat inner portions A-1510 to rotate around the annulus A-1310. The rotation of the slat inner portions A-1510 places the plurality of slats A-1500 along and adjacent to the pole A-1100 to prevent the slat external surfaces A-1550 from being expose to the sunlight and heat.

In the closed position, the exposure of the slat external surfaces A-1550 to the sunlight and heat is minimized and prevent the plurality of photovoltaic modules, the plurality of thermoelectric generator modules C-1000 from generating the solar input electricity SIe and the thermal input electricity HIe, respectively. Consequently, in the closed position cooling by the plurality of thermoelectric cooling modules D-1000 is minimized.

The solar cooling system 1000 and its elements, e.g. the plurality of photovoltaic modules B-1000; the plurality of thermoelectric generator modules C-1000; the plurality of thermoelectric cooling modules D-1000; and/or the battery assembly E-1000, is not limited to be mounted on the support structure A-1000 presented and can be mounted on other types of support structures such as, house roofs, walls, carports, vehicle bodies, or any other supports.

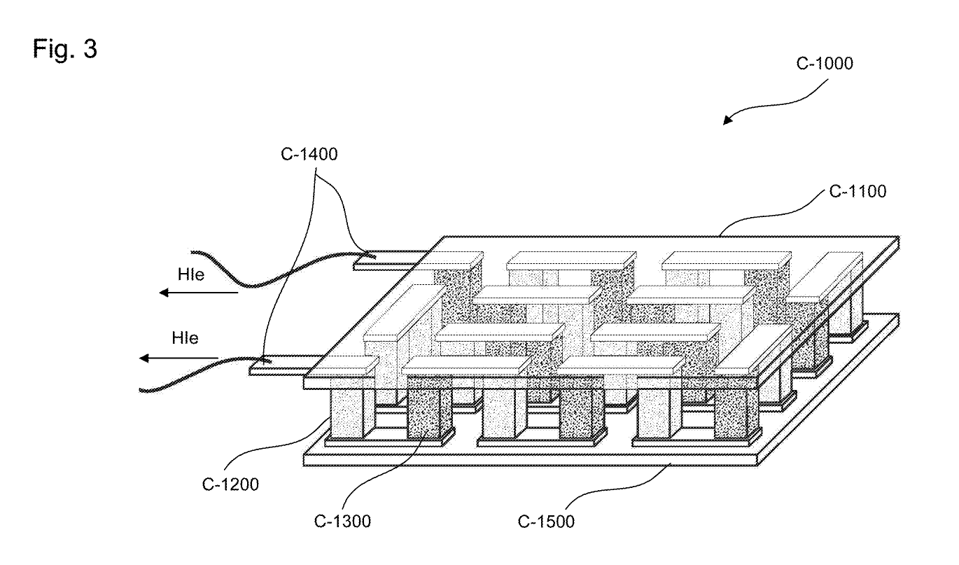

FIG. 3 is diagram of a thermoelectric generator module C-1000 of the solar cooling system 1000, according to certain aspects of the disclosure.

Each thermoelectric generator module of the plurality of thermoelectric generator modules C-1000 can include a first top plate C-1100 that receives heat, a first bottom plate C-1500 opposite to the first top plate C-1100, a first plurality of n-type blocks C-1200, a first plurality of p-type blocks C-1300 adjacent to the plurality of n-type blocks C-1200, a first pair of electrical connections C-1400 that connects in series the first plurality of n-type blocks C-1200 with the first plurality of p-type blocks C-1300 to create p-n junctions.

Temperature differences between the first top plate C-1100 and the first bottom plate C-1500 generates on the p-n junctions a Seebeck effect that produces temperature differences between the first top plate C-1100 and the first bottom plate C-1500 that lead to electrical potential that is collected by the first pair of electrical connections C-1400 and produce the thermal input electricity HIe that is sent to the battery assembly E-1000.

The first top plate C-1100 and the first bottom plate C-1500 can be made of thermally conducting and electrically insulating materials, e.g. ceramic materials, to enhance heat transfer between the first top plate C-1100 and the first bottom plate C-1500 and prevent electrical disturbance on the p-n junctions from happening.

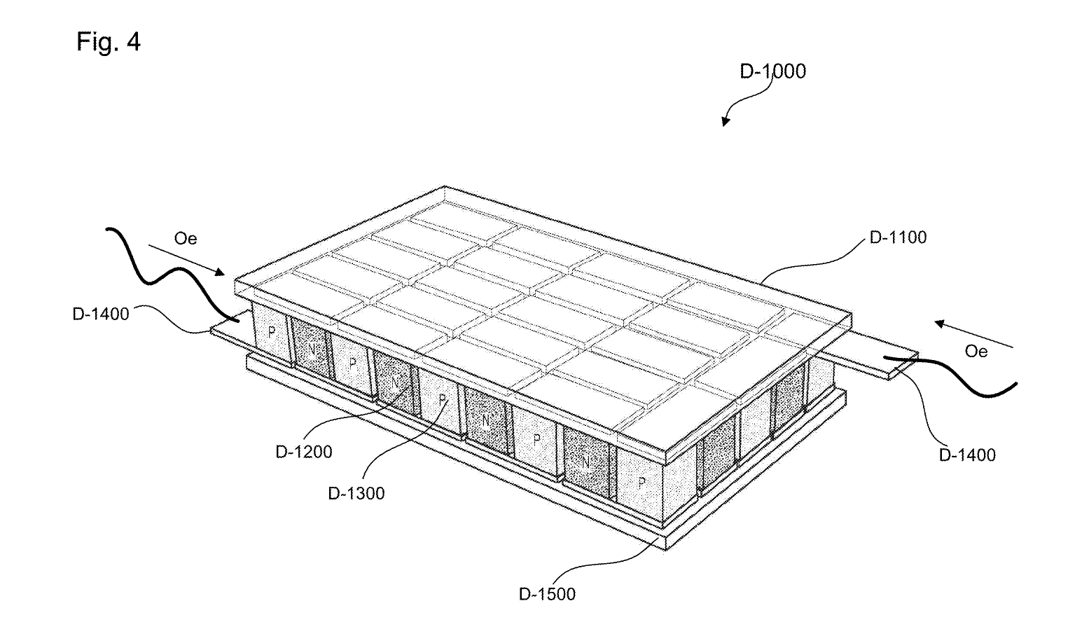

FIG. 4 is diagram of a thermoelectric cooling module D-1000 of the solar cooling system 1000, according to certain aspects of the disclosure.

Each thermoelectric cooling module of the plurality of thermoelectric cooling modules D-1000 can include a second top plate D-1100 that is exposed to the sunlight light and heat, a second bottom plate D-1500 opposite to the second top plate D-1100, a second plurality of n-type blocks D-1200, a second plurality of p-type blocks D-1300 adjacent to the second plurality of n-type blocks D-1200, a second pair of electrical connections D-1400 that connects the second plurality of n-type blocks D-1200 with the second plurality of p-type blocks D-1300.

The second pair of electrical connections D-1400 can receive the output electricity Oe provided by the battery assembly E-1000, and generate a Peltier effect at junctions between the second plurality of n-type blocks D-1200 and the second plurality of p-type blocks D-1300 that produces an electrical potential which leads temperature difference from the second bottom plate D-1300 to the second top plate D-1200.

Similarly as the first top plate C-1100 and the first bottom plate C-1500, the second top plate D-1100 and the second bottom plate D-1500 can be made of thermally conducting and electrically insulating materials, e.g. ceramic materials, to enhance heat transfer between the second top plate D-1100 and the second bottom plate D-1500 and prevent electrical disturbance on the p-n junctions from happening.

FIG. 5 is a schematic view of a battery assembly E-1000 of the solar cooling system 1000, according to certain aspects of the disclosure.

The battery assembly E-1000 can include a battery E-1100 with a battery voltmeter E-1110, a charge regulator E-1200 with a rectifier circuit E-1250 electrically connecting the plurality of photovoltaic modules B-1000 and the plurality of thermoelectric generator modules C-1000 to the battery E-1100, an input voltmeter E-1310 positioned between the rectifier circuit E-1250 and the plurality of photovoltaic modules B-1000 and the plurality of thermoelectric generator modules C-1000, a temperature sensor detector E-1350, an output voltage adjuster E-1410 positioned between the battery E-1100 and the plurality of thermoelectric cooling modules D-1000, and an electronic control unit F-1000 that can read the battery voltmeter E-1110, the input voltmeter E-1310, and actuate the output voltage adjuster E-1410, and the charge regulator E-1200.

The charge regulator E-1200 and the rectifier circuit E-1250 can receive, rectify, and regulate the solar input electricity SIe from the plurality of photovoltaic modules B-1000 and the thermal input electricity HIe from the plurality of thermoelectric generator modules C-1000 to provide regulated input electricity RIe to the battery E-1100. The charge regulator E-1200 can prevent transferring over voltages to the battery E-1100 to enhance battery performance and lifespan by providing the regulated input electricity RIe as an average of the solar input electricity SIe and thermal input electricity HIe over a predetermined period of time.

The charge regulator E-1200 can be a stand-alone device, as illustrated in FIG. 5, or circuitry integrated to the battery E-1100. To provide the regulated input electricity RIe, the charge regulator E-1200 can rely on Pulse Width Modulation (PWM) and/or Maximum Power Point-Tracker (MPPT) technologies.

In addition, the charge regulator E-1200 can be coupled with the rectifier circuit E-1250, as illustrated in FIG. 5, to rectify the solar input electricity SIe and/or the thermal input electricity HIe that can be alternative currents and provide a direct current to the charge regulator E-1200.

The battery E-1100 can store the regulated input electricity RIe to be concurrently or later used in external elements of the solar cooling system 1000, e.g. electronic devices, and/or electric chargers, through the electrical connection E-1120, e.g. an USB connection, and/or an electrical outlet, as illustrated in FIG. 5. The battery E-1100 can be a single or a plurality of alkaline batteries, lead acid batteries, lithium-ion batteries, or the like.

The electrical control unit F-1000 can monitor and control the solar cooling system 1000 by receiving reading signals from the battery voltmeter E-1110 indicative of a charge level of the battery E-1100, reading signals from the input voltmeter E-1310 indicative of a voltage value of the solar input electricity SIe and the thermal input electricity HIe, and reading signals from the temperature E-1350 indicative of temperatures around the pole A-1100, as well as by providing to the charge regulator E-1200 command signals indicative of a voltage decrease of the solar input electricity SIe and the thermal input electricity HIe, to the output voltage adjuster E-1410 command signals indicative of a voltage increase of the output electricity Oe.

The electrical control unit F-1000 and functionalities associated with the electrical control unit F-1000 will be described in details in following paragraphs and figures.

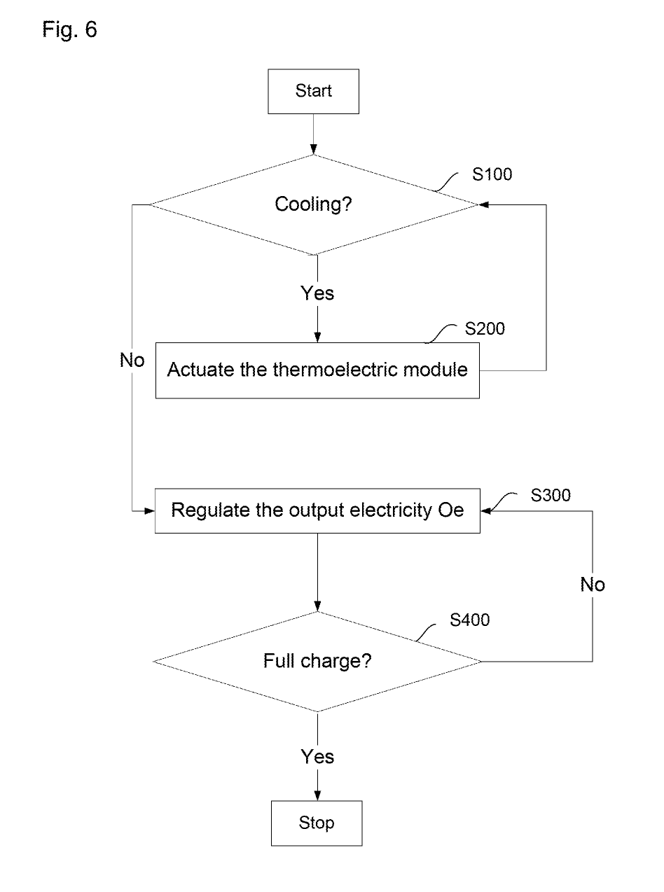

FIG. 6 is a flow chart of a method for providing cooling through the solar cooling system 1000, according to certain aspects of the disclosure.

In a step S100, a demand or request to provide cooling is detected or recorded. The command or request to provide cooling can be manually detected by entry from the user, via an electrical switch or an I/O interface D-1016, e.g. graphical user interface, of the electronic control unit F-1000 or be automatically detected when the support structure is articulated in the open position via an electrical switch operated by the bottom latch A-1110 and/or the top latch A-1120 of the pole A-1100.

If the command or request to provide cooling is detected or recorded the process to a step S200. Otherwise, the process goes to a step S300.

In the step S200, the plurality of thermoelectric cooling modules D-1000 is actuated to provide cooling. The plurality of thermoelectric cooling modules D-1000 can be actuated via the output voltage adjuster E-1410 of the battery assembly E-1000, as illustrated in FIG. 5, and through software instructions executed by the electrical control unit F-1000. For example, the electrical control unit F-1000 can be configured to determine voltage values for the output electricity Oe and send action signals to the output voltage adjuster E-1410 to provide the voltage values for the output electricity Oe to the plurality of thermoelectric cooling modules D-1000. The voltage values for the output electricity Oe can be determined based on a temperature difference between temperature values around the pole A-1100, provided by reading signals from the temperature sensor E-1350 as illustrated in FIG. 5, and preset temperature values, entered manually by the user via an electrical level selector switch, e.g. variable switch, rheostat, and/or potentiometer, or an I/O interface D-1016, e.g. graphical user interface, of the electronic control unit F-1000.

Then, the process goes back to the step S100.

In a step S300, the solar input electricity SIe is regulated to provide the regulated input electricity RIe via the charge regulator E-1200 and through software instructions executed by the electrical control unit F-1000. For example, the electrical control unit F-1000 can actuate the charge regulator E-1200 to reduce, e.g. through heat dissipation, the solar input electricity SIe when voltage values of the solar input electricity SIe are above a predetermined maximum battery threshold. The predetermined maximum battery threshold can correspond to voltage values for which the battery E-1100 can be damaged.

In a step S400, it is detected if the battery E-1100 is fully charged. The full charge of the battery E-1100 can be determined with a voltage value of the battery E-1100 that is measured via the battery voltmeter E-1110, as illustrated in FIG. 5, and through software instructions executed by the electrical control unit F-1000. For example, the full charge of the battery E-1100 can be detected if the voltage value of the battery E-1100 is above a maximum voltage charge of the battery E-1100.

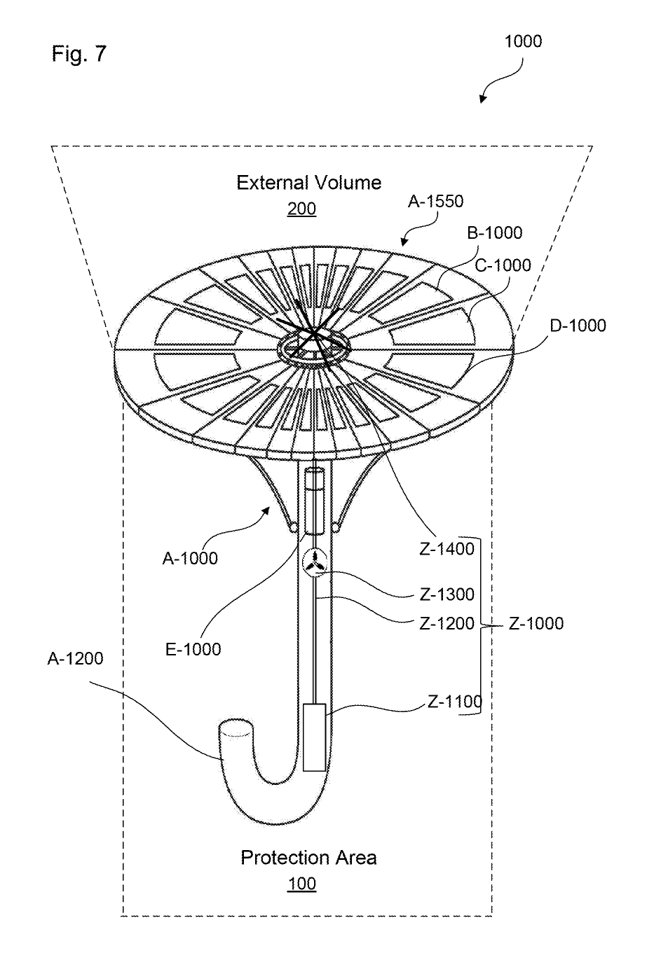

If the full charge of the battery E-1100 is detected, the process stops. Otherwise, the process goes back to the step S300. FIG. 7 is a perspective view of the solar cooling system 1000 with an evaporation system Z-1000, according to certain aspects of the disclosure.

FIG. 7 is a perspective view of the solar cooling system 1000 with an evaporation system Z-1000, according to certain aspects of the disclosure.

In addition, the solar cooling system 1000 can include an evaporation system Z-1000 to further enhance cooling of the protected area 100.

The evaporation system Z-1000 can include a reservoir Z-1100 positioned in the internal volume of the pole A-1100, as illustrated in FIG. 7, and/or outside the pole A-1100, a nozzle Z-1400 positioned on an upper portion of the cap A-1300, a conduit Z-1200 extending between the reservoir Z-1100 and the nozzle Z-1400, and a pump Z-1300 positioned between the reservoir Z-1100 and the nozzle Z-1400.

The reservoir Z-1100 can contain a coolant, e.g. water, the pump Z-1300 powered by the battery assembly E-1000 can carry the coolant from the reservoir Z-1100 to the nozzle Z-1400 through the conduit Z-1200, and the nozzle Z-1400 can distribute the coolant on the slat external surfaces A-1550 and notably on the plurality of thermoelectric cooling modules D-1000. The coolant present on the slat external surfaces A-1550 can be vaporized to the external volume 200 due to heat and sunlight to provide supplementary cooling on the protected area 100.

In addition, the evaporation of the coolant can reduce gradient temperature between the second top plate D-1100 and the second bottom plate D-1500 of the plurality of thermoelectric cooling modules D-1000 and consequently reduces the electrical consumption of the plurality of thermoelectric modules D-1000.

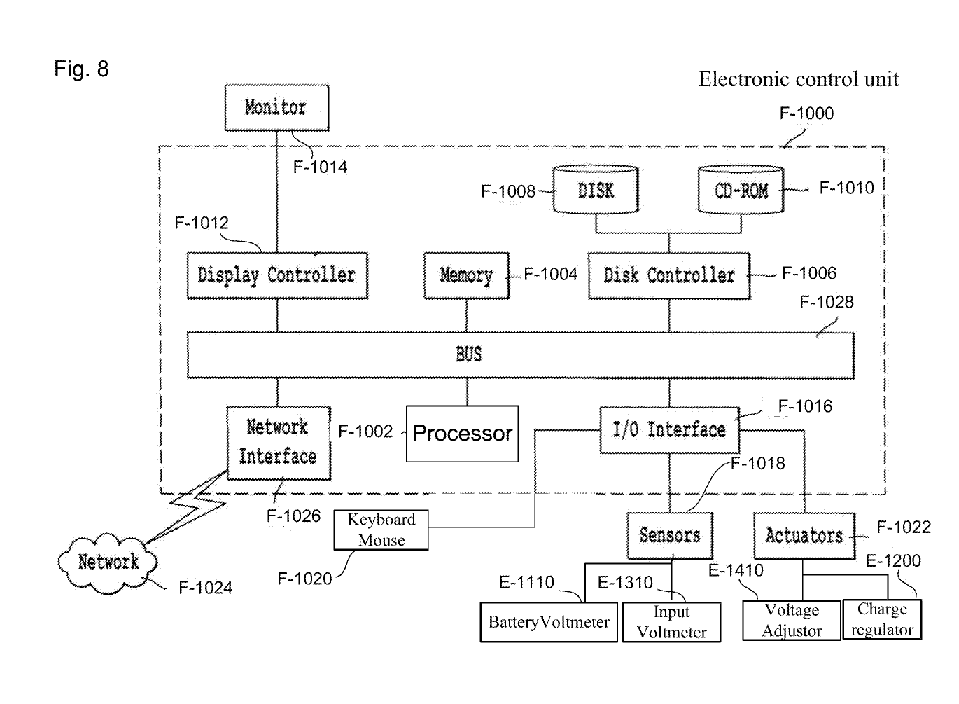

FIG. 8 is a schematic view of a hardware diagram of an electrical control unit F-1000 for operating the solar cooling system 1000, according to certain aspects of the disclosure.

FIG. 8 depicts the electrical control unit F-1000 to control the apparatus to draft a patent application. As shown in FIG. 8, systems, operations, and processes in accordance with this disclosure may be implemented using a processor F-1002 or at least one application specific processor (ASP). The processor F-1002 may utilize a computer readable storage medium, such as a memory F-1004 (e.g., ROM, EPROM, EEPROM, flash memory, static memory, DRAM, SDRAM, and their equivalents), configured to control the processor F-1002 to perform and/or control the systems, operations, and processes of this disclosure. Other storage mediums may be controlled via a disk controller F-1006, which may control a hard disk drive F-1008 or optical disk drive F-1010.

The processor F-1002 or aspects thereof, in an alternate embodiment, can include or exclusively include a logic device for augmenting or fully implementing this disclosure. Such a logic device includes, but is not limited to, an application-specific integrated circuit (ASIC), a field programmable gate array (FPGA), a generic-array of logic (GAL), and their equivalents. The processor F-1002 may be a separate device or a single processing mechanism. Further, this disclosure may benefit form parallel processing capabilities of a multi-cored processor.

In another aspect, results of processing in accordance with this disclosure may be displayed via a display controller F-1012 to a monitor F-1014 that may be peripheral to or part of the electrical control unit F-1000. Moreover, the monitor F-1014 may be provided with a touch-sensitive interface to a command/instruction interface. The display controller F-1012 may also include at least one graphic processing unit for improved computational efficiency. Additionally, the electrical control unit F-1000 may include an I/O (input/output) interface F-1016, provided for inputting sensor data from sensors F-1018 and for outputting orders to actuators F-1022. The sensors F-1018 and actuators F-1022 are illustrative of any of the sensors and actuators described in this disclosure. For example, the sensors F-1018 can include the battery voltmeter E-1110 and the input voltmeter E-1310 and the actuators F-1022 can include the output voltage adjuster E-1410 and the charge regulator E-1200.

Further, other input devices may be connected to an I/O interface F-1016 as peripherals or as part of the electrical control unit F-1000. For example, a keyboard or a pointing device such as a mouse F-1020 may control parameters of the various processes and algorithms of this disclosure, and may be connected to the I/O interface F-1016 to provide additional functionality and configuration options, or to control display characteristics. Actuators F-1022 which may be embodied in any of the elements of the apparatuses described in this disclosure may also be connected to the I/O interface F-1016.

The above-noted hardware components may be coupled to the network F-1024, such as the Internet or a local intranet, via a network interface F-1026 for the transmission or reception of data, including controllable parameters to a mobile device. A central BUS F-1028 may be provided to connect the above-noted hardware components together, and to provide at least one path for digital communication there between.

The foregoing discussion discloses and describes merely exemplary embodiments of an object of the present disclosure. As will be understood by those skilled in the art, an object of the present disclosure may be embodied in other specific forms without departing from the spirit or essential characteristics thereof. Accordingly, the present disclosure is intended to be illustrative, but not limiting of the scope of an object of the present disclosure as well as the claims.

Numerous modifications and variations on the present disclosure are possible in light of the above teachings. It is therefore to be understood that within the scope of the appended claims, the disclosure may be practiced otherwise than as specifically described herein.

What is claimed is:

1. A solar cooling system comprising:
a support structure articulable between an open position and a closed position, the support structure having:
a pole,
a cap affixed to an upper portion of the pole, and
a plurality of slats rotatably affixed to the cap, wherein
in the open position the plurality of slats radially protrudes from the cap and in the closed position the plurality of slats is adjacent to the pole;
a plurality of photovoltaic modules affixed to the plurality of slats to receive sunlight and provide solar electricity when the support structure is in the open position;
a plurality of thermoelectric generator modules affixed to the plurality of slats to receive temperature gradient and provide thermal electricity when the support structure is in the open position;
a plurality of thermoelectric cooling modules affixed to the plurality of slats to receive input electricity and provide cooling when the support structure is in the open position; and
a battery assembly affixed to the pole and electrically connected to the plurality of photovoltaic modules and the plurality of thermoelectric generator modules to receive, regulate, and store the solar electricity and the thermal electricity and provide the input electricity.

2. The solar cooling system of claim 1, wherein the pole includes a top latch to maintain the support structure in the closed position and a bottom latch to maintain the support structure in the open position.

3. The solar cooling system of claim 2, wherein the support structure further include a runner ring that slides along the pole between the bottom latch and the top latch.

4. The solar cooling system of claim 3, wherein the support structure further includes a plurality of arms radially extending between the runner ring and the plurality of slats.

5. The solar cooling system of claim 1, wherein the support structure further includes a cap affixed to a top portion of the pole to rotatably support the plurality of slats.

6. The solar cooling system of claim 5, wherein the cap includes an annulus on which each slat of the plurality of slats is rotatably affixed.

7. The solar cooling system of claim 1, wherein the battery assembly is positioned inside an internal volume of the pole.

8. The solar cooling system of claim 1, wherein the pole includes an electrical connection connected to a battery of the battery assembly.

9. The solar cooling system of claim 1, wherein each thermoelectric generator module of the plurality of thermoelectric generator modules includes a plurality of n-type blocks, a plurality of p-type blocks electrically connected to the plurality of n-type blocks to create p-n junctions that receives the temperature gradient and generate the thermal electricity.

10. The solar cooling system of claim 9, wherein each thermoelectric generator module further includes a pair of plates to enclose the p-n junctions.

11. The solar cooling system of claim 10, wherein the pair of plates is made of a thermally conducting and electrically insulating material.

12. A solar cooling system comprising:
a support structure;
a plurality of photovoltaic modules affixed to the support structure to receive sunlight and provide solar electricity;
a plurality of thermoelectric generator modules affixed to support structure to receive temperature gradient and provide thermal electricity;
a plurality of thermoelectric cooling modules affixed to the support structure to receive input electricity and provide cooling;
a battery assembly affixed to the support structure and electrically connected to the plurality of photovoltaic modules and the plurality of thermoelectric generator modules to receive, regulate, and store the solar electricity and the thermal electricity and provide the input electricity; and
an electrical control unit configured to detect a cooling demand and to actuate the plurality of thermoelectric cooling modules to provide cooling.

13. The solar cooling system of claim 12, wherein the electrical control unit is further configured to detect if a battery of the battery assembly is fully charged.

14. The solar cooling system of claim 12, wherein each thermoelectric generator module of the plurality of thermoelectric generator modules includes a plurality of n-type blocks, a plurality of p-type blocks electrically connected to the plurality of n-type blocks to create p-n junctions that receives the temperature gradient and generate the thermal electricity.

15. The solar cooling system of claim 14, wherein each thermoelectric generator module further includes a pair of plates to enclose the p-n junctions.

16. The solar cooling system of claim 15, wherein the pair of plates is made of a thermally conducting and electrically insulating material.

17. A solar cooling system comprising:
a support structure;
a plurality of photovoltaic modules affixed to the support structure to receive sunlight and provide solar electricity;
a plurality of thermoelectric generator modules affixed to support structure to receive temperature gradient and provide thermal electricity;
a plurality of thermoelectric cooling modules affixed to the support structure to receive input electricity and provide cooling; and
a battery assembly affixed to the support structure and electrically connected to the plurality of photovoltaic modules and the plurality of thermoelectric generator modules to receive, regulate, and store the solar electricity and the thermal electricity and provide the input electricity.

18. The solar cooling system of claim 17, wherein each thermoelectric generator module of the plurality of thermoelectric generator modules includes a plurality of n-type blocks, a plurality of p-type blocks electrically connected to the plurality of n-type blocks to create p-n junctions that receives the temperature gradient and generate the thermal electricity.

19. The solar cooling system of claim 18, wherein each thermoelectric generator module further includes a pair of plates to enclose the plurality of p-n junctions.

20. The solar cooling system of claim 19, wherein the pair of plates is made of a thermally conducting and electrically insulating material.
